(19) United States
(12) Patent Application Publication
(10) Pub. No.: US 2026/0372157 A1
(43) Pub. Date: Nov. 19, 2026

(54) SEMICONDUCTOR DEVICE WITH REDUCED JOINT GAP, BONDING STRUCTURE OF THE SAME, METHOD OF MANUFACTURING THE SAME, AND METHOD OF BONDING THE SAME

(71) Applicant: Samsung Electronics Co., Ltd., Suwon-si (KR)

(72) Inventors: Yusuke Tanaka, Yokohama (JP); Keiichiro Hattori, Yokohama (JP); Toshiki Furutani, Yokohama (JP); Takashi Kariya, Yokohama (JP)

(21) Appl. No.: 19/678,529

(22) Filed: May 15, 2026

(30) Foreign Application Priority Data
May 19, 2025 (JP) 2025-083264

(51) Int. Cl. H10W 72/20; H10P 50/24; H10P 50/28; H10W 20/00; H10W 20/20; H10W 72/29; H10W 74/10; H10W 90/00; H10W 90/26

(52) U.S. Cl. CPC H10W 72/287; H10W 72/29; H10W 74/134; H10W 90/26; H10W 90/722; H10P 50/24; H10P 50/28; H10W 20/0245; H10W 20/211

(57) ABSTRACT

A semiconductor device includes a semiconductor chip including a first main surface and a second main surface opposite to the first main surface, a wiring configured to penetrate the semiconductor chip from the first main surface to the second main surface, a plurality of first electrodes overlapping the wiring on the first main surface, a solder bump on the first electrode, a non-conductive layer on the first main surface and the solder bump, and a plurality of second electrodes on the wiring on the second main surface, and a concave portion is arranged in at least one of a space between the adjacent first electrodes and a space between the adjacent second electrodes.

### CROSS-REFERENCE TO RELATED APPLICATION

This application is based on and claims priority under 35 U.S.C. § 119 to Japan Patent Application No. 2025-083264, filed on May 19, 2025, in the Japan Patent Office, the disclosure of which is incorporated by reference herein in its entirety.

### BACKGROUND

A packaging technology for stacking and bonding a plurality of semiconductor devices including wirings formed by through-silicon vias (TSVs) is known. For example, in Patent Document 1 (Publication of Japanese Patent No. 2024-097288), a bonding structure of a semiconductor device is disclosed in which adjacent semiconductor devices are bonded to each other via solder bumps.

A high bandwidth memory (HBM) is a memory standard that employs a bonding structure to interconnect semiconductor devices. In the HBM, each semiconductor device has a memory device such as dynamic random access memory (DRAM).

### SUMMARY

The disclosure relates to a semiconductor device, a bonded structure of the semiconductor device, a method of manufacturing the semiconductor device, and a method of bonding the semiconductor device.

In a high bandwidth memory (HBM), because a plurality of semiconductor devices (such as dynamic random access memory (DRAM) dies) having small surface areas are stacked, heat dissipation efficiency may be low. Particularly, in the HBM, the semiconductor devices are bonded and connected to each other with solder bumps therebetween without being in close contact with each other, thereby reducing the heat dissipation efficiency (thermal conductivity may be low). As the semiconductor device's temperature increases, the performance of a memory device may deteriorate. Further, as the temperature of the semiconductor device increases, a leakage current from the memory device may increase. Accordingly, an increased number of refresh operations may be required to reliably retain the memory contents of the memory device. However, the refresh operations may further increase the temperature of the semiconductor device.

According to some embodiments, a space (a joint gap) between adjacent semiconductor devices may be reduced in order to improve the heat dissipation efficiency of the bonding structure. When the bonding structure of the semiconductor device is formed, a first electrode (an electrode on which solder bumps are formed) of one semiconductor device and a second electrode of another semiconductor device may face each other and be thermally compressed (thermal compression bonding (TCB)). Accordingly, the first electrode of one semiconductor device and the second electrode of the other semiconductor device may be bonded to each other by arranging solder bumps therebetween to form a bonding portion of the two electrodes. A non-conductive layer may exist between the bonding portions of the electrodes. In other words, a plurality of bonding portions of the electrodes may be formed, and the non-conductive layers may be filled in the space therebetween. The non-conductive layer may be formed on a surface of a first electrode side of each semiconductor device, and may flow during the thermocompression to be arranged between the bonding portions of the electrodes.

It may be possible to increase a load of thermocompression to reduce the joint gap. However, even when the load of thermocompression increases, the joint gap may not be reduced as expected. During the thermocompression, by bonding the first electrode of one semiconductor device and the second electrode of the other semiconductor device by arranging a solder bump therebetween, and at the same time, by flowing and disposing a non-conductive material (a material constituting the non-conductive layer) between the bonding portions of the first and second electrodes and removing the remaining non-conductive material to the outer side of the bonding structure of the semiconductor devices, the semiconductor devices may be bonded to each other. The non-conductive material removed to the outer side of the bonding structure of the semiconductor device may be referred to as a non-conductive film (NCF) fillet.

However, in the HBM, because the distance between solder bumps (a bump pitch) is small and the number of solder bumps is large, the non-conductive material may not flow sufficiently. Accordingly, it may be difficult to reduce the joint gap sufficiently.

On the other hand, when the joint gap is reduced by increasing the load on a semiconductor device (such as a DRAM die) during a mounting operation, a large amount of non-conductive material may move outside the bonding structure of the semiconductor device (that is, many NCF fillets are formed), and thus the NCF fillet may sometimes reach a back surface of the semiconductor device (a surface opposite to the surface where the bonding portion of the electrode is formed). In this case, it may be possible that the NCF fillet becomes an obstacle when another semiconductor device is bonded to the bonding structure of the corresponding semiconductor device.

A thin drawing operation on the non-conductive layer may be performed as a solution to this issue. However, the thin drawing of the non-conductive layer may not be easy.

In addition, the issue described above may not be limited to the HBM, and may occur in the entire bonding structure of the semiconductor device described above.

The disclosure provides a semiconductor device capable of reducing a joint gap with a relatively low load and reducing the amount of the NCF fillet.

According to an aspect of the disclosure, there is provided a semiconductor device including a semiconductor chip including a first main surface and a second main surface opposite to the first main surface, a wiring that extends through the semiconductor chip from the first main surface to the second main surface, a plurality of first electrodes overlapping the wiring on the first main surface, a solder bump on each first electrode, a non-conductive layer on the first main surface and the solder bump, and a plurality of second electrodes overlapping the wiring on the second main surface. The semiconductor chip includes a concave portion arranged in at least one of a space between the adjacent first electrodes or a space between the adjacent second electrodes.

According to another aspect of the disclosure, there is provided a method of manufacturing a semiconductor, the method including a first operation of forming, in a semiconductor substrate including a first main surface and a second main surface opposite to the first main surface, a wiring extending between the first main surface and the second main surface, a second operation of forming a plurality of first electrodes on the wiring and the first main surface, a third operation of forming a solder bump on each first electrode, a fourth operation of forming a plurality of second electrodes on the wiring and the second main surface, a fifth operation of forming a concave portion in the semiconductor substrate and in at least of a space between the first electrodes and a space between the second electrodes, and a sixth operation of forming a non-conductive layer on the first main surface and the solder bump.

According to another aspect of the disclosure, there is provided a method of bonding a plurality of semiconductor devices, the method including an eighth operation of preparing a plurality of the semiconductor device described above, a ninth operation of stacking a plurality of the semiconductor devices such that a first electrode of a first semiconductor device faces a second electrode of a second semiconductor device, and a tenth operation of forming a bonding portion by melting a solder bump and a non-conductive layer by using thermocompression and bonding the first electrode of the first semiconductor device to the second electrode of the second semiconductor device by using the solder bump, and filling the non-conductive layer at least in a space between the bonding portions and in the concave portion in each of the first semiconductor device and the second semiconductor device.

### BRIEF DESCRIPTION OF THE DRAWINGS

Embodiments of the disclosure will be more clearly understood from the following detailed description taken in conjunction with the accompanying drawings in which:

FIG. 1A is a diagram schematically illustrating a cross-sectional structure of an example semiconductor device;

FIG. 1B is a plan view schematically illustrating an example semiconductor device;

FIG. 2 is a diagram schematically illustrating an example concave portion;

FIG. 3 is a diagram schematically illustrating an example concave portion;

FIG. 4 is a diagram schematically illustrating an example concave portion;

FIG. 5 is a diagram schematically illustrating an example concave portion;

FIG. 6 is a diagram schematically illustrating an example concave portion;

FIG. 7 is a diagram schematically illustrating an example concave portion;

FIG. 8A is a diagram illustrating an example manufacturing process of an example semiconductor device;

FIG. 8B is a diagram illustrating an example manufacturing process of an example semiconductor device;

FIG. 8C is a diagram illustrating an example manufacturing process of an example semiconductor device;

FIG. 8D is a diagram illustrating an example manufacturing process of an example semiconductor device;

FIG. 8E is a diagram illustrating an example manufacturing process of an example semiconductor device;

FIG. 8F is a diagram illustrating an example manufacturing process of an example semiconductor device;

FIG. 8G is a diagram illustrating an example manufacturing process of an example semiconductor device;

FIG. 8H is a diagram illustrating an example manufacturing process of an example semiconductor device;

FIG. 8I is a diagram illustrating an example manufacturing process of an example semiconductor device;

FIG. 9 is a diagram illustrating an example bonding structure of an example semiconductor device;

FIG. 10 is a diagram illustrating an example bonding process of example semiconductor devices;

FIG. 11A is a cross-sectional scanning electron microscope (SEM) image representing an example second electrode and its surrounding structure immediately after the start of dry etching;

FIG. 11B is a cross-sectional SEM image representing the example second electrode and its surrounding structure 6 minutes after the start of dry etching;

FIG. 11C is a cross-sectional SEM image representing the example second electrode and its surrounding structure 12 minutes after the start of dry etching;

FIG. 11D is a cross-sectional SEM image representing the example second electrode and its surrounding structure 18 minutes after the start of dry etching; and

FIG. 12 is a graph illustrating a relationship between an etching depth (μm) and a joint gap (μm) of an example concave portion.

### DETAILED DESCRIPTION

In some embodiments, a semiconductor device 1 may include: a semiconductor chip 20 including a first main surface 20a and a second main surface 20b opposite to the first main surface 20a; a wiring 23 formed to penetrate the semiconductor chip 20 from the first main surface 20a to the second main surface 20b; a plurality of first electrodes 21 overlapping the wiring 23 on the first main surface 20a; a solder bump 24 formed on the first electrode 21; a non-conductive layer 28 formed on the first main surface 20a and the solder bump 24; and a plurality of second electrodes 22 overlapping the wiring 23 on the second main surface 20b, wherein a concave portion 30 is formed in at least one of a space between the first electrodes 21 or a space between the second electrodes 22. The concave portion 30 may include a trench in the semiconductor chip 20. The concave portion is a portion of a surface that is recessed inward relative to an adjacent surface region, and is not limited to any particular curvature, depth, or geometric profile.

The concave portion 30 may be formed in the space between the adjacent second electrodes 22.

Insulating layers 26 and 27 may be formed on the first main surface 20a and the second main surface 20b, respectively, and the concave portion 30 may be formed on at least one of the insulating layer 26 or the insulating layer 27.

The concave portion 30 may penetrate at least one of the insulating layer 26 or the insulating layer 27 to reach the semiconductor chip 20.

An oxide layer may be formed on a surface of the concave portion 30 facing the semiconductor chip 20.

The concave portion 30 may be formed in at least one of a space between the adjacent first electrodes 21 or a space between the adjacent second electrodes 22, and in addition, may be formed up to a back surface of at least one of the first electrode 21 or the second electrode 22.

The shape of a side surface 32 of the concave portion 30 may include at least one of an inclined planar shape or a curved shape.

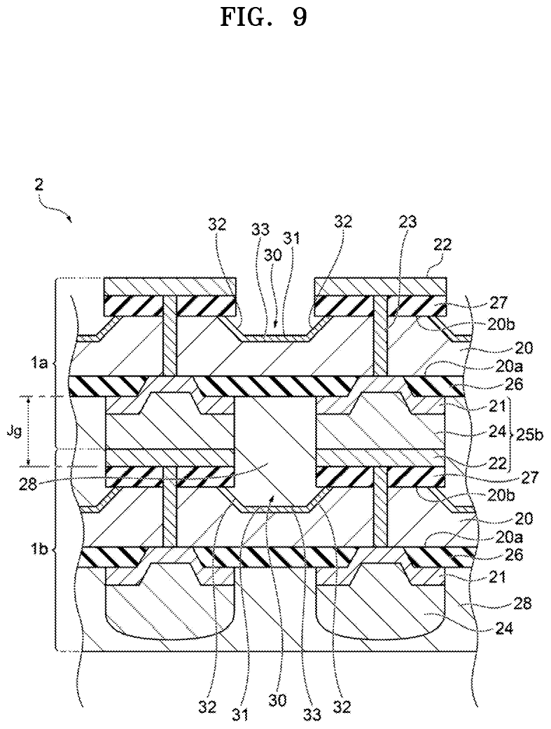

A bonding structure of the semiconductor device 1 according to some embodiments may include a bonding structure of a semiconductor device in which a plurality of semiconductor devices described above are bonded, the first electrode 21 of a first semiconductor device (1a in FIG. 9) may be bonded to the second electrode 22 of a second semiconductor device (1b in FIG. 9) by using the solder bump 24 to constitute a second bonding portion 25b, and in addition, the non-conductive layer 28 of the first semiconductor device 1a may be filled at least in a space between the second bonding portion 25b and the concave portion 30.

A method of manufacturing a semiconductor device according to some embodiments may include a method of manufacturing the semiconductor device 1 described above, and may include: a first operation of forming, in a semiconductor substrate 200 including the first main surface 20a and the second main surface 20b opposite to the first main surface 20a, the wiring 23 extending between the first main surface 20a and the second main surface 20b by using a through-silicon via (TSV) technique; a second operation of forming the plurality of first electrodes 21 on the wiring 23 on a side of the first main surface 20a; a third operation of forming the solder bump 24 on the first electrode 21; a fourth operation of forming a plurality of second electrodes 22 on the wiring 23 on a side of the second main surface 20b; a fifth operation of forming the concave portion 30 in at least one the space between the first electrodes 21 and the space between the second electrodes 22; and a sixth operation of forming the non-conductive layer 28 on the first main surface 20a and the solder bump 24.

The method of manufacturing the semiconductor device 1 described above may include a seventh operation of forming the first and second insulating layers 26 and 27 on at least one of the first main surface 20a or the second main surface 20b, and in the fifth operation, by etching at least the second insulating layer 27, the concave portion 30 may be formed.

In the fifth operation, by etching at least the second insulating layer 27, the concave portion 30 may be formed.

In the fifth operation, by etching at least the second insulating layer 27 and the semiconductor substrate 200, the concave portion 30 may be formed.

In the fifth operation, the surface of the concave portion 30 formed in the semiconductor substrate 200 may be oxidized.

A method of bonding a semiconductor device according to some embodiments may include a method of bonding a semiconductor device, in which the first semiconductor device 1a and the second semiconductor device 1b described above are bonded together, the method including: an eighth operation of preparing a plurality of both the first semiconductor device 1a and the second semiconductor device 1b; a ninth operation of stacking the plurality of first and second semiconductor devices 1a and 1b such that the first electrode 21 of the first semiconductor device 1a faces the second electrode 22 of the second semiconductor device 1b; and a tenth operation of forming the second bonding portion 25b by melting the solder bump 24 and the non-conductive layer 28 by using the thermocompression and bonding the first electrode 21 of the first semiconductor device 1a and the second electrode 22 of the second semiconductor device 1b by using the solder bump 24, and in addition, filling the non-conductive layer 28 at least in the space between the second bonding portions 25b and in the concave portion 30.

Hereinafter, detailed embodiments of the disclosure are described with reference to the accompanying drawings. Furthermore, in the following description, the identical reference numerals are assigned to components common in each embodiment, and duplicate descriptions are omitted. In addition, the drawings are schematic. In other words, in the drawings, dimensions of each component and ratios between components may be different from actual values. In addition, the dimensions of each component and the ratios between the components may be different from each other between the drawings.

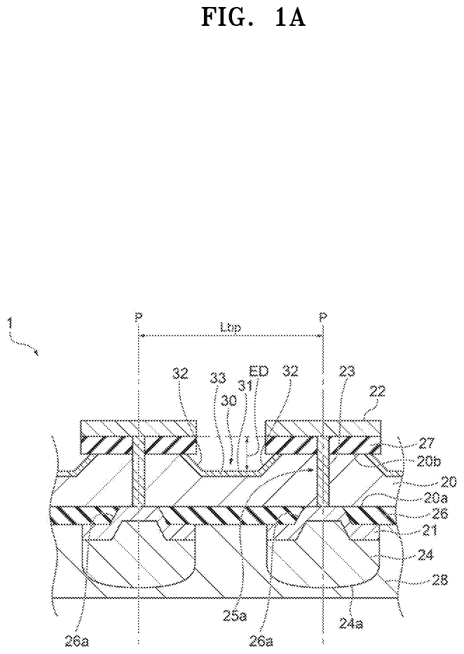

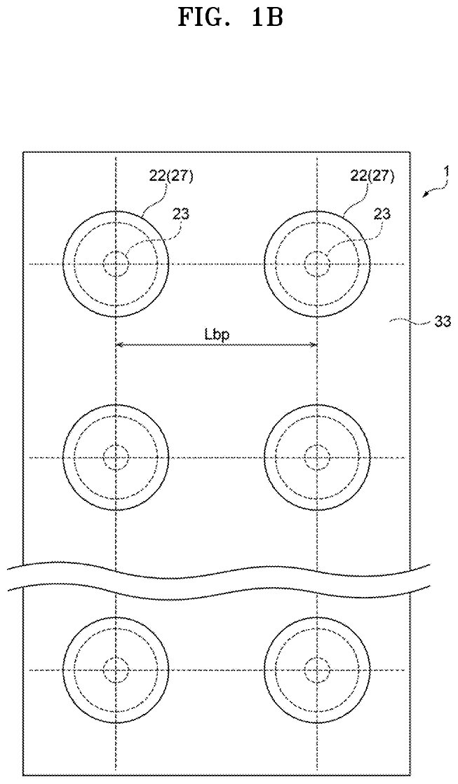

Firstly, based on FIGS. 1A and 1B, the configuration of the semiconductor device 1 according to some embodiments is described. FIG. 1A is a diagram schematically illustrating a cross-sectional structure of the semiconductor device 1. FIG. 1B is a plan view of the semiconductor device 1.

The semiconductor device 1 may include, for example, a processor, a memory, a logic integrated circuit (IC), or an analog IC, etc. The semiconductor device 1 may include the semiconductor chip 20, the plurality of first electrodes 21, the plurality of second electrodes 22, the wiring 23, the solder bump 24, the first insulating layer 26, the second insulating layer 27, and the non-conductive layer 28.

The semiconductor device 1 may include a first bonding portion 25a, which includes the first electrode 21, the second electrode 22, the wiring 23, and the solder bump 24 as one set, in plural. In the semiconductor device 1, a distance Lbp between the adjacent first bonding portions 25a, that is, a bump pitch, may be, for example, about 10 μm to about 20 μm or less. In this case, the distance Lbp) between the adjacent first bonding portions 25a may be referred to as the distance between an axis line P of the wiring 23 and the axis line P of the other wiring 23 adjacent thereto.

The semiconductor substrate 200 may include a substrate on which electronic circuits are formed in each certain region of a wafer by using semiconductor integrated circuit manufacturing technology. The semiconductor chip 20 may include a chip (die) obtained by dividing the semiconductor substrate 200 into certain regions. According to some embodiments, the wafer may include a silicon (Si) substrate. However, the wafer is not limited thereto, but may include a compound semiconductor substrate, such as a gallium nitride (GaN) substrate and a Si carbide (SiC) substrate, and the type of the substrate is not limited.

The semiconductor chip 20 may include the first main surface 20a and the second main surface 20b. The first main surface 20a may include a surface (front side) on which, for example, electronic circuits are formed. The second main surface 20b may include a surface (back side) opposite to the first main surface 20a. The first insulating layer 26 may be formed on the first main surface 20a of the semiconductor chip 20, and the second insulating layer 27 may be formed on the second main surface 20b of the semiconductor chip 20. The first insulating layer 26 and the second insulating layer 27 may include, for example, SiO₂, SiN, oxide-nitride-oxide (ONO), etc. The thicknesses of the first insulating layer 26 and the second insulating layer 27 may be 3 μm or less.

In addition, in the description below, a surface, on which electronic circuits are formed, (front side) of the semiconductor substrate 200 before the semiconductor chip 20 is divided may be denoted as a “first main surface 200a”, and a surface on the opposite side of the first main surface 200a (back side) of the semiconductor substrate 200 may be denoted as a “second main surface 200b”.

The wiring 23 may be formed to penetrate the semiconductor chip 20 from the first main surface 20a of the semiconductor chip 20 to the second main surface 20b of the semiconductor chip 20. In a direction vertical to the first main surface 20a and the second main surface 20b (stacking direction), the wiring 23 may penetrate the semiconductor chip 20 and the second insulating layer 27. The wiring 23 may include a TSV formed by using, for example, TSV technology. The wiring 23 may include a metal material, such as copper (Cu), tungsten (W), and aluminum (Al). On a wall surface of a hole through which the wiring 23 penetrates, an oxide layer that is the same as an oxide layer 33 described below may be formed.

The first electrode 21 and the second electrode 22 may function as pads for electrically connecting the semiconductor devices 1 to each other. The first electrode 21 and the second electrode 22 may be connected to the electronic circuit formed on the semiconductor chip 20.

The first electrode 21 may be formed on the wiring 23 on the first main surface 20a of the semiconductor chip 20 and the first insulating layer 26. In other words, the first electrode 21 may be formed on the first main surface 20a of the semiconductor chip 20 such that the first electrode 21 overlaps the wiring 23 in a stacking direction of the semiconductor device 1 (direction of the axis line P of the wiring 23). The first electrode 21 may be in contact with an end edge portion of the wiring 23 on the side of the first main surface 20a. By using an etching operation, a through hole 26a may be formed in the first insulating layer 26, and by using this through hole 26a, the first electrode 21 may be in contact with the end edge portion of the wiring 23 on the side of the first main surface 20a.

The second electrode 22 may be formed on the wiring 23 on the side of the second main surface 20b of the semiconductor chip 20 and on the second insulating layer 27. In other words, the second electrode 22 may be formed on the second main surface 20b of the semiconductor chip 20 such that the second electrode 22 overlaps the wiring 23 in the stacking direction of the semiconductor device 1 (direction of the axis line P of the wiring 23). The second electrode 22 may be in contact with the end edge portion of the wiring 23 on the side of the second main surface 20b. The second electrode 22 may be formed in a flat shape.

The solder bump 24 may include a metal material for electrically connecting the semiconductor devices 1 to each other, or electrically connecting an interposer and a substrate, such as a print substrate, to the semiconductor device 1. The metal material may include, for example, tin (Sn) as a main material. The solder bump 24 may include, for example, a lead-free solder, such as a Sn—Ag type and a Sn—Ag—Cu type. The solder bump 24 may be formed on the first electrode 21. A surface 24a of the solder bump 24 (a surface opposite to the first electrode 21) is illustrated to have a gentle convex shape, but is not limited thereto.

The non-conductive layer 28 may be formed on the first main surface 20a and the solder bump 24. The non-conductive layer 28 may cover the solder bumps 24 on the first main surface 20a. The non-conductive layer 28 may be formed to prevent conductivity between adjacent solder bumps 24, etc. The non-conductive layer 28 may be formed by, for example, laminating a non-conductive film (for example, non-conductive film (NCF)) on the entire surface on the side of the first main surface 20a, or doping a non-conductive material in a liquid phase onto the entire surface on the side of the first main surface 20a.

The thickness of the non-conductive layer 28 is not particularly limited, and may be about 2 μm to about 10 μm. When the thickness of the non-conductive layer 28 is less than 2 μm, film-making of a non-conductive material may be difficult. In addition, when the thickness of a non-conductive film is less than the total height of the solder bump 24 and the first electrode 21, a space between the solder bumps 24 may not be sufficiently filled with the non-conductive layer 28, and accordingly a void may be formed. Furthermore, when the semiconductor devices 1 are bonded to each other, and the amount of the non-conductive material between the solder bumps 24 is not sufficient, a void may be formed. In some embodiments, the non-conductive layer 28 is formed by doping the non-conductive material, uniform or effective doping of the non-conductive material may be difficult to achieve.

When the thickness of the non-conductive layer 28 exceeds 10 μm, it may be difficult to reduce the joint gap. Furthermore, when the semiconductor devices 1 are bonded to each other, a lot of NCF fillets may be generated. These issues may be solved by deeply forming the concave portion 30 to be described below, but it may be difficult to form the concave portion 30. For example, the time of etching may be lengthened. Furthermore, when the concave portion 30 reaches the semiconductor chip 20, the semiconductor chip 20 may be exposed, and thus a corresponding exposed portion may be covered by an oxide layer. When the exposed portion is covered by an oxide layer, a process for this operation may be necessary.

The concave portion 30 may be formed in a space between adjacent second electrodes 22 (hereinafter, referred to as a space between second electrodes). As illustrated in FIG. 1B, there may be multiple second electrodes adjacent to a certain second electrode 22 (in up, down, left, and right directions, and in an inclined direction). As illustrated in FIG. 1B, the concave portion 30 may be formed over the entire region between the second electrodes, or the concave portion 30 may be formed in at least a portion of a space between at least one set of adjacent second electrodes. In an example illustrated in FIG. 1A, the concave portion 30 may penetrate the second electrode 22 and the second insulating layer 27, and may reach a back surface of the second insulating layer 27. A bottom surface 31 of the concave portion 30 may generally have a flat surface shape, and the parts of the side surfaces 32 of the concave portion 30 formed on the semiconductor chip 20 may be inclined and planar. Furthermore, the oxide layer 33 may be formed on a surface of the concave portion 30 formed in the semiconductor chip 20. The oxide layer 33 may protect the semiconductor chip 20. In addition, the concave portion 30 according to some embodiments may mean that the concave portion 30 is formed at least between the second insulating layers 27 (furthermore, in the semiconductor chip 20 under the second insulating layer 27), but may not mean a space between the second electrodes 22.

In some embodiments, because the concave portion 30 is formed between the second electrodes 22, when the semiconductor devices 1 are bonded to each other, the non-conductive material may flow into the concave portion 30. Accordingly, the joint gap may be reduced by using a relatively low load, and in addition, the amount of the NCF fillet may be reduced. Particularly, in an example of FIG. 1, because the concave portion 30 reaches up to the back surface of the second insulating layer 27, a relatively larger amount of the non-conductive material may flow into the concave portion 30. Furthermore, because the non-conductive layer 28 may have an anchor effect, when the semiconductor devices 1 are bonded to each other, the bonding strength thereof may be improved. Furthermore, because an interface distance between the second electrodes 22 increases, an interface leakage may decrease.

The concave portion 30 may be formed between the second electrodes 22 by using an etching technique. In the example of FIG. 1, the concave portion 30 may be formed by cutting the second insulating layer 27 using a dry etching, and furthermore, cutting the semiconductor substrate 200 using an anisotropic etching is described below. In addition, the surface of the concave portion 30 formed on the semiconductor substrate 200 may be oxidized (for example, plasma oxidized, etc.). Accordingly, the oxide layer 33 may be formed in the corresponding portion.

A depth ED of the concave portion 30 (a distance from the surface of the second insulating layer 27 to the bottom surface 31 of the concave portion 30, or an etching depth) may be about 0.5 μm to about 3.0 μm. When the depth ED is less than 0.5 μm, only a small amount of non-conductive material may flow into the concave portion 30, and the effect of some embodiments may not be sufficiently realized. When the depth ED of the concave portion 30 exceeds 3.0 μm, the concave portion 30 may frequently reach the semiconductor chip 20, and thus it may be preferred to form the oxide layer 33 described above. However, a process for the forming operation may be required. When the thickness of the second insulating layer 27 is formed to be 3.0 μm or more, forming the oxide layer 33 may be omitted, but a process for thickening the second insulating layer 27 is necessary.

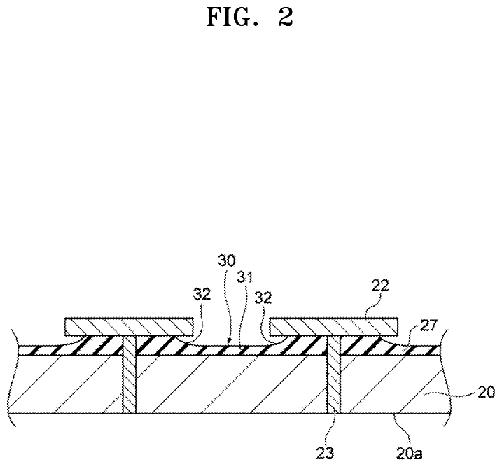

Next, with reference to FIGS. 2 through 7, various modified examples of the concave portion 30 are described. In addition, in FIGS. 2 through 7, the components under the first main surface 20a of the semiconductor chip 20 are omitted. FIG. 2 is a diagram schematically illustrating a first modified example of the concave portion 30. In the first modified example, the concave portion 30 may be formed on the second insulating layer 27. Furthermore, the side surface 32 of the concave portion 30 may be curved. Furthermore, the concave portion 30 may be formed up to the back surface of the second electrode 22. The concave portion 30 may be formed by performing a wet etching on the second insulating layer 27.

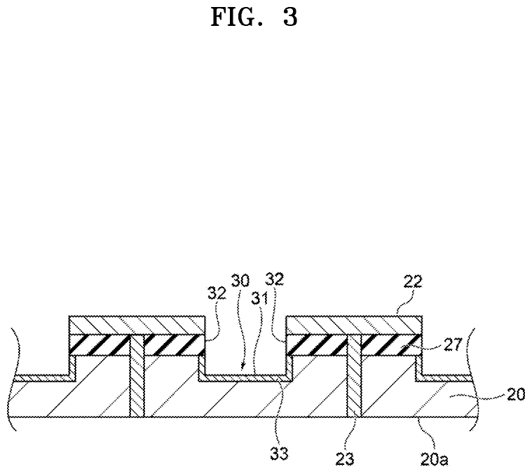

FIG. 3 is a diagram schematically illustrating a second modified example of the concave portion 30. In the second modified example, the concave portion 30 may be formed on the second insulating layer 27. Furthermore, the side surface 32 of the concave portion 30 may be vertically oriented. The concave portion 30 may be formed by performing a dry etching on the second insulating layer 27.

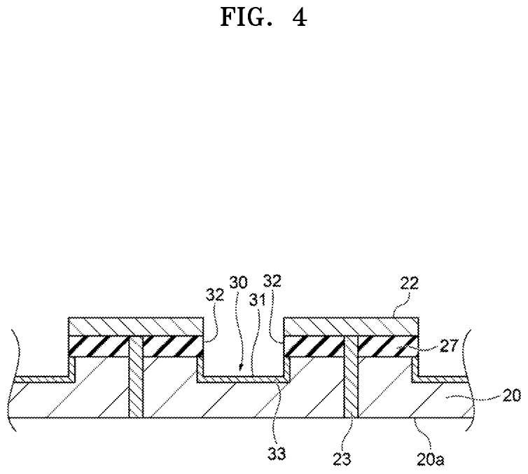

FIG. 4 is a diagram schematically illustrating a third modified example of the concave portion 30. In the third modified example, the concave portion 30 may be formed in the second insulating layer 27 and in the semiconductor chip 20. Furthermore, the side surface 32 of the concave portion 30 may be vertically oriented. The oxide layer 33 may be formed on the surface of the concave portion 30 formed in the semiconductor chip 20. After the second insulating layer 27 and the semiconductor substrate 200 are dry etched as described below, the concave portion 30 may be formed by performing an oxidation process (for example, plasma oxidation) on the exposed portion of the semiconductor substrate 200.

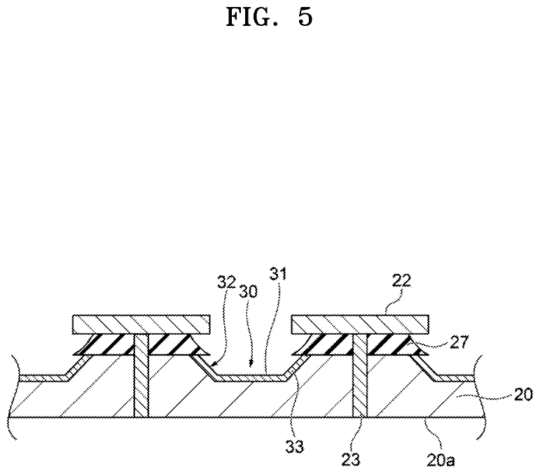

FIG. 5 is a diagram schematically illustrating a fourth modified example of the concave portion 30. In the fourth modified example, the concave portion 30 may be formed in the second insulating layer 27 and the semiconductor chip 20. Furthermore, among the side surfaces 32 of the concave portion 30, a part of the side surfaces 32 formed in the second insulating layer 27 may be curved, and a part of the side faces 32 formed in the semiconductor chip 20 may be inclined and planar. The oxide layer 33 may be formed on the surface of the concave portion 30 formed in the semiconductor chip 20. Furthermore, the concave portion 30 may be formed up to the back surface of the second insulating layer 27. After a wet etching is performed on the second insulating layer 27, and an anisotropic etching is performed on the semiconductor substrate 200 as described below, the concave portion 30 may be formed by additionally performing an oxidation process (for example, plasma oxidation) on the exposed portion of the semiconductor substrate 200.

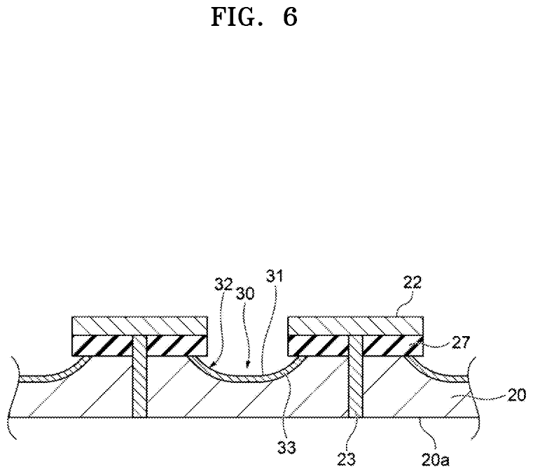

FIG. 6 is a diagram schematically illustrating a fifth modified example of the concave portion 30. In the fifth modified example, the concave portion 30 may be formed in the second insulating layer 27 and in the semiconductor chip 20. Furthermore, among the side surfaces 32, a portion formed in the second insulating layer 27 may be vertically oriented, and a portion formed in the semiconductor chip 20 may be curved. In addition, in the fifth modified example, the concave portion 30 may be continuously curved from the bottom surface 31 up to the side surface 32. The oxide layer 33 may be formed on the surface of the concave portion 30 formed in the semiconductor chip 20. Furthermore, the concave portion 30 may be formed up to the back surface of the second insulating layer 27. After a dry etching is performed on the second insulating layer 27, and an isotropic etching is performed on the semiconductor substrate 200 as described below, the concave portion 30 may be formed by additionally performing an oxidation process (for example, plasma oxidation) on the exposed portion of the semiconductor substrate 200.

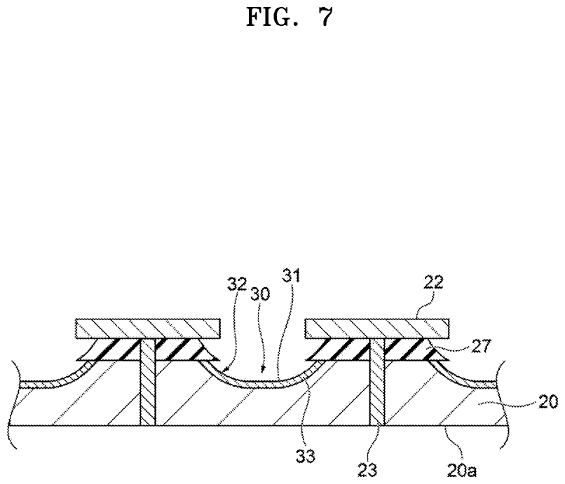

FIG. 7 is a diagram schematically illustrating a sixth modified example of the concave portion 30. In the sixth modified example, the concave portion 30 may be formed in the second insulating layer 27 and in the semiconductor chip 20. Furthermore, among the side surfaces 32 of the concave portion 30, a portion formed in the second insulating layer 27 may be curved, and a portion formed in the semiconductor chip 20 may also be curved. In addition, in the sixth modified example, the concave portion 30 may be continuously curved from the bottom surface 31 up to the side surface 32. The oxide layer 33 may be formed on the surface of the concave portion 30 formed in the semiconductor chip 20. Furthermore, the concave portion 30 may be formed up to the back surface of the second insulating layer 27. After a wet etching is performed on the second insulating layer 27, and an isotropic etching is performed on the semiconductor substrate 200 as described below, the concave portion 30 may be formed by additionally performing an oxidation process (for example, plasma oxidation) on the exposed portion of the semiconductor substrate 200.

The same effects as described above may be obtained in any modified example.

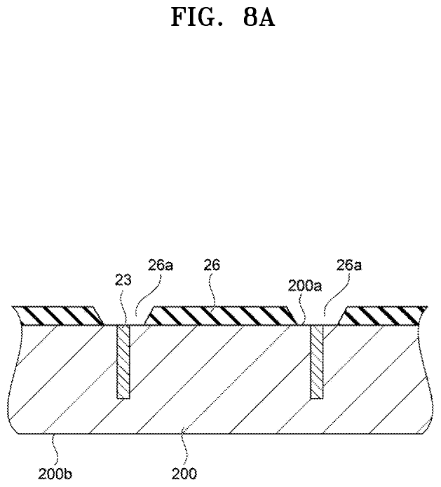

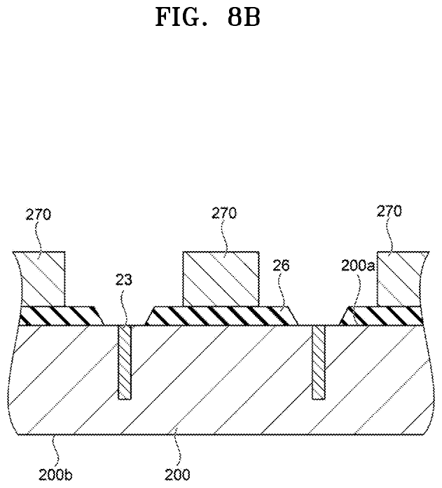

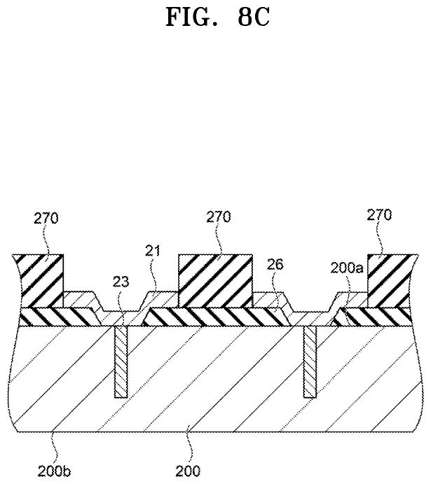

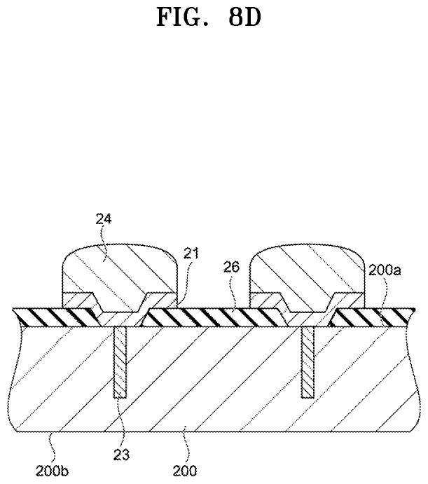

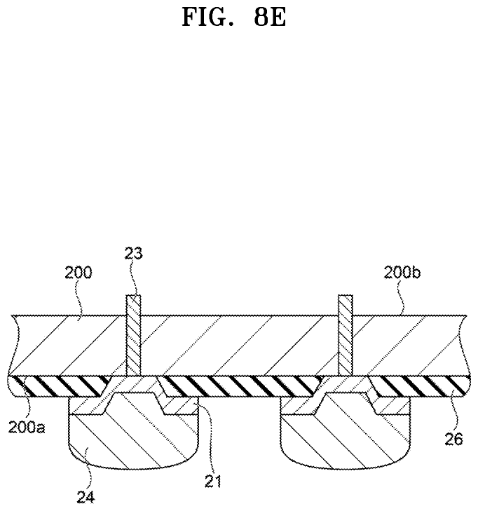

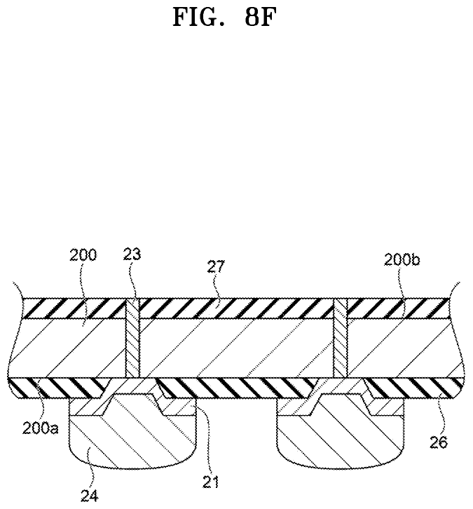

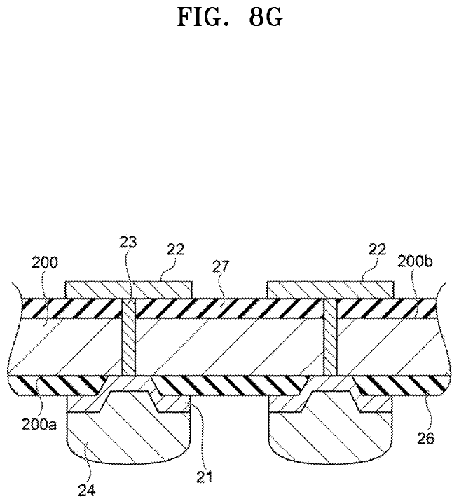

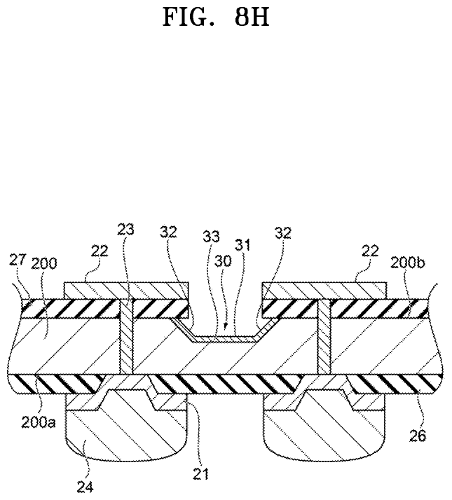

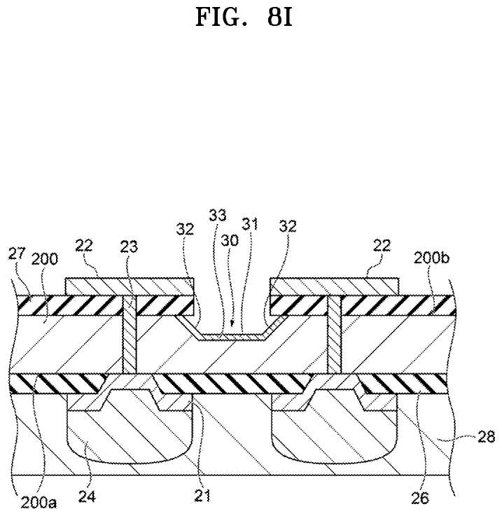

Next, with reference to FIGS. 8A through 8I, a method of manufacturing the semiconductor device 1 is described. FIGS. 8A through 8I are diagrams illustrating examples of a manufacturing process of the semiconductor device 1, according to embodiments.

Firstly, using semiconductor integrated circuit manufacturing technology, the semiconductor substrate 200 may be prepared on which an integrated circuit is formed in a certain region of a wafer (for example, a silicon substrate). Next, as illustrated in FIG. 8A, the wiring 23 may be formed in the semiconductor substrate 200 (first operation). For example, after the first insulating layer 26 (for example, a silicon oxide (SiO2) layer is formed on the first main surface 200a of the semiconductor substrate 200 (seventh operation), the first insulating layer 26 in a region for forming the wiring 23 may be selectively removed. Accordingly, the through hole 26a may be formed. Next, by using the TSV technology, a hole toward the second main surface 200b may be formed on a bottom surface of the through hole 26a, and a metal material may fill in the hole. On a wall surface of the corresponding hole, an oxide layer that is the same as the oxide layer 33 may also be formed. The metal material may include, for example, Cu, W, or Al. Accordingly, the TSV may be formed as the wiring 23. In this case, a diameter of TSV may be 2.5 μm or less.

Next, the first electrode 21 may be formed on the wiring 23 on the side of the first main surface 200a of the semiconductor substrate 200 (second operation). For example, firstly, as illustrated in FIG. 8B, after a seed layer (not illustrated) is formed on the entire surface of the first main surface 200a of the semiconductor substrate 200, a resist pattern 270 may be formed in a region other than the region for forming the first electrode 21 and the solder bump 24 by using a photolithography technology. In this case, a metal material of the seed layer may include, for example, nickel (Ni). Next, for example, by using a plating technology (for example, electroplating), the metal material may be deposited in a region that is not masked by the resist pattern 270. The metal material may include, for example, Ni or gold (Au). Accordingly, as illustrated in FIG. 8C, the first electrode 21 may be formed on the wiring 23 on the side of the first main surface 200a.

Next, the solder bump 24 may be formed on the first electrode 21 (third operation). For example, by using the resist pattern 270 used in the second operation as a mask, and by using, for example, the plating technology (for example, electroplating), the metal material (for example, Sn—Ag-based solder) may be deposited in a region that is not masked by the resist pattern 270. Thereafter, the resist pattern 270 may be removed, and at the same time, the seed layer on the first insulating layer 26 of the semiconductor substrate 200 may be removed. Accordingly, as illustrated in FIG. 8D, the solder bump 24 may be formed on the first electrode 21.

Next, the second electrode 22 may be formed on the wiring 23 on the side of the second main surface 200b of the semiconductor substrate 200 (fourth operation). For example, firstly, as illustrated in FIG. 8E, by taking the side of the second main surface 200b of the semiconductor substrate 200 as a surface of a processing object, and using the grinding and reactive ion etching (RIE) processes, a portion of the side of the second main surface 200b of the semiconductor substrate 200 may be removed to protrude from the semiconductor substrate 200.

Next, as illustrated in FIG. 8F, by using, for example, a chemical vapor deposition (CVD) process, the second insulating layer 27 may be formed on the second main surface 200b of the semiconductor substrate 200 (seventh operation). Thereafter, by using a chemical mechanical polishing (CMP) process, the side of the second main surface 200b of the semiconductor substrate 200 may be planarized.

Next, in the same manner as the second operation, after the seed layer (not illustrated) is formed on the entire surface of the side of the second main surface 200b of the semiconductor substrate 200, the resist pattern (not illustrated) may be formed in a region other than a region for forming the second electrode 22. Thereafter, as illustrated in FIG. 8G, by using the plating technology (for example, electroplating), the metal material may be deposited in a region that is not masked by the resist pattern. The metal material may include, for example, Ni or Au. Next, the resist pattern may be removed. Accordingly, the second electrode 22 may be formed on the wiring 23 on the side of the second main surface 200b.

Next, as illustrated in FIG. 8H, by using the etching technology, the concave portion 30 may be formed between the second electrode 22 (fifth operation). In the example of FIG. 8H, by using the second electrode 22 as a mask, the second insulating layer 27 may be dry etched. Next, the semiconductor substrate 200 may go through an anisotropic etching process. Next, the exposed portion of the semiconductor substrate 200 may be oxidized (for example, plasma oxidized). Accordingly, the concave portion 30 may be formed between the second electrodes 22. This concave portion 30 may have the same configuration as the concave portion 30 illustrated in FIG. 1. In the fifth operation, the concave portion 30 according to each of the modified examples described above may be formed.

Next, as illustrated in FIG. 8I, the non-conductive layer 28 may be formed on the entire surface on the side of the first main surface 200a of the semiconductor substrate 200 (sixth operation). The method of forming the non-conductive layer 28 is not particularly limited, and for example, may be formed by laminating the non-conductive film (for example, NCF) on the entire surface on the side of the first main surface 200a, or doping the non-conductive material in a liquid phase on the entire surface on the side of the first main surface 200a.

Next, by performing a dicing process, the semiconductor substrate 200 may be divided into a plurality of semiconductor chips 20. Accordingly, as illustrated in FIG. 1, a plurality of semiconductor devices 1 includes the semiconductor chip 20, the wiring 23, the first electrode 21, the second electrode 22, the solder bump 24, the non-conductive layer 28, and the concave portion 30.

According to some embodiments, a semiconductor device may be manufactured using a simple process, and the semiconductor device 1 illustrated in FIG. 1 may be manufactured.

Next, with reference to FIG. 9, a bonding structure 2 of a semiconductor device is described. In the example of FIG. 9, two semiconductor devices 1, that is, the first semiconductor device 1a and the second semiconductor device 1b may be bonded to each other. The bonding structure 2 of a semiconductor device may be manufactured using a method of bonding a semiconductor device described below.

In the bonding structure 2 of a semiconductor device, the first electrode 21 of the first semiconductor device 1a and the second electrode 22 of the second semiconductor device 1b may be bonded to each other by using the solder bump 24, thereby forming a second bonding portion 25b, and in addition, the non-conductive layer 28 of the first semiconductor device 1a may fill a space between the second bonding portions 25b and in the concave portion 30 of the second semiconductor device 1b. Similarly, in the bonding structure 2 of a semiconductor device according to some embodiments, the non-conductive layer 28 may fill not only the space between the second bonding portions 25b but also the concave portion 30 of the second semiconductor device 1b. In other words, when the first semiconductor device 1a is bonded to the second semiconductor device 1b, the non-conductive material constituting the non-conductive layer 28 may flow into the concave portion 30 of the second semiconductor device 1b. Accordingly, even without a big load, a joint gap Jg (in this case, a distance from a surface of the first insulating layer 26 of the first semiconductor device 1a to a surface of the second insulating layer 27 of the second semiconductor device 1b is defined as the joint gap Jg) may be reduced, and in addition, the amount of the NCF fillet may be reduced.

By reducing the joint gap Jg, electrical resistance and thermal resistance of the bonding structure 2 of a semiconductor device may be reduced to improve heat dissipation efficiency.

In addition, the joint gap Jg may be, for example, about 1 μm to about 7 μm. When the joint gap Jg is less than 1 μm, the first electrode 21 of the semiconductor device 1a, the solder bump 24, and the second electrode 22 of the second semiconductor device 1b may need to be formed thin to prevent a non-uniformity in bonding surfaces thereof. Furthermore, a slight inclination of the first semiconductor device 1a and the second semiconductor device 1b may cause a bonding defect. When the joint gap Jg is greater than 7 μm, the heat dissipation efficiency of the bonding structure 2 of a semiconductor device may deteriorate. This issue may be significant when the bonding structure 2 of a semiconductor device is applied to a high bandwidth memory (HBM).

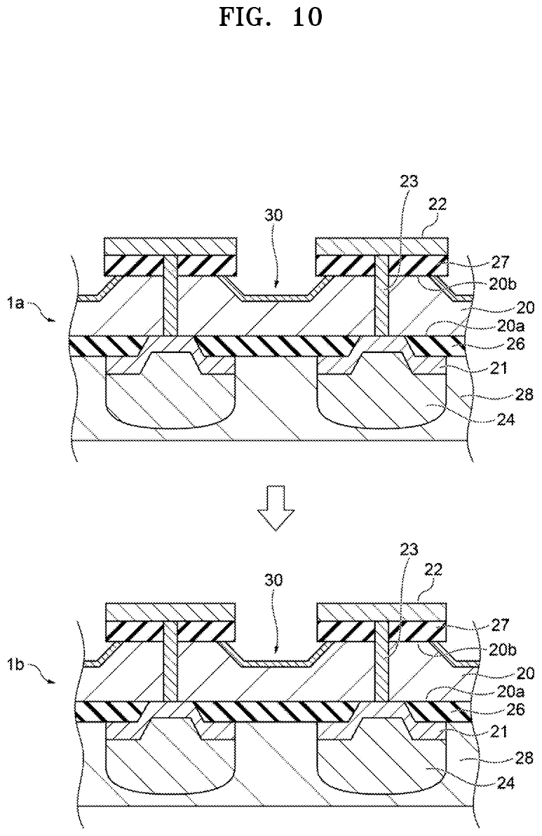

Next, with reference to FIG. 10, a method of bonding of a semiconductor device is described. FIG. 10 is a diagram illustrating an example of a bonding process of semiconductor devices, according to some embodiments. Firstly, the first semiconductor device 1a and the second semiconductor device 1b may be prepared (eighth operation). Next, the first and second semiconductor devices 1a and 1b may be stacked such that the first electrode 21 of the first semiconductor device 1a faces the second electrode 22 of the second semiconductor device 1b (ninth operation).

Next, by forming the second bonding portion 25b by melting the solder bump 24 of the first semiconductor device la and the non-conductive layer 28 by using the thermocompression bonding technology such as thermal compression bonding (TCB), and bonding the first electrode 21 of the first semiconductor device 1a to the second electrode 22 of the second semiconductor device 1b by using the solder bump 24, and at the same time, by flowing the non-conductive material constituting the non-conductive layer 28, the space between the second bonding portions 25b and the concave portion 30 of the second semiconductor device 1b may be filled (tenth operation).

By using the method of bonding of a semiconductor device according to some embodiments, when the first semiconductor device 1a is bonded to the second semiconductor device 1b, the non-conductive material constituting the non-conductive layer 28 may flow into the concave portion 30 of the second semiconductor device 1b. Accordingly, even without a big load, the joint gap Jg may be reduced, and in addition, the amount of the NCF fillet may be reduced.

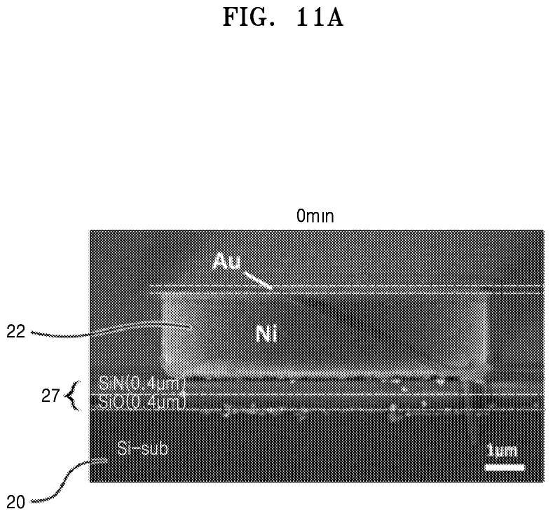

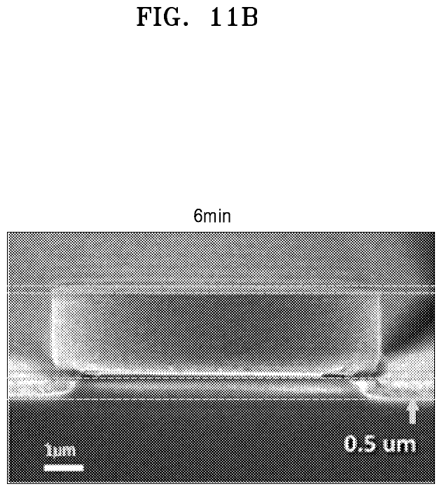

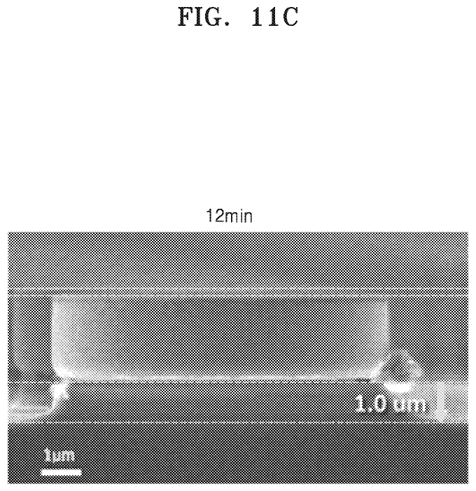

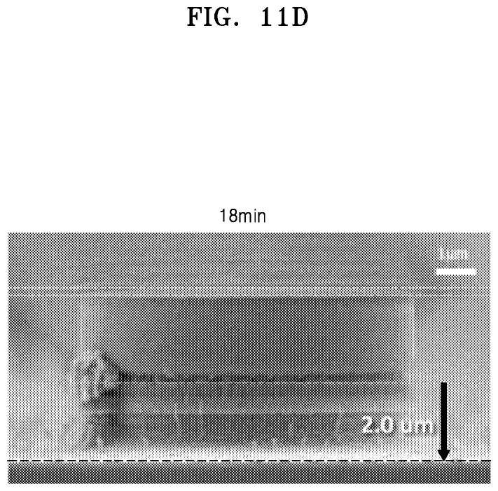

Next, some embodiments are described. First, with reference to FIGS. 11A to 11D, it is described that the concave portion 30 may be formed by using an etching technology. FIGS. 11A to 11D show cross-sectional scanning electron microscope (SEM) images representing the second electrode 22 and its surrounding structure when dry etching is being performed.

In the present experiment, a Si chip has been used as the semiconductor chip 20, and a structure in which SiO₂ of a thickness of 0.4 μm and SiN of a thickness of 0.4 μm are stacked has been used as the second insulating layer 27. Au-plated Ni has been used as the second electrode 22. Dry etching conditions can include CHF₃/SF₆ (volume rate)=38/12, 10 Pa, and 250 W. A state of the second insulating layer 27 and the semiconductor chip 20 immediately after the start of the etching is shown in FIG. 11A, that 6 minutes thereafter is shown in FIG. 11B, that 12 minutes thereafter is shown in FIG. 11C, and that 18 minutes thereafter is shown in FIG. 11D. As illustrated in the diagrams, it may be identified that the second insulating layer 27 and the semiconductor chip 20 have been etched by an etching gas.

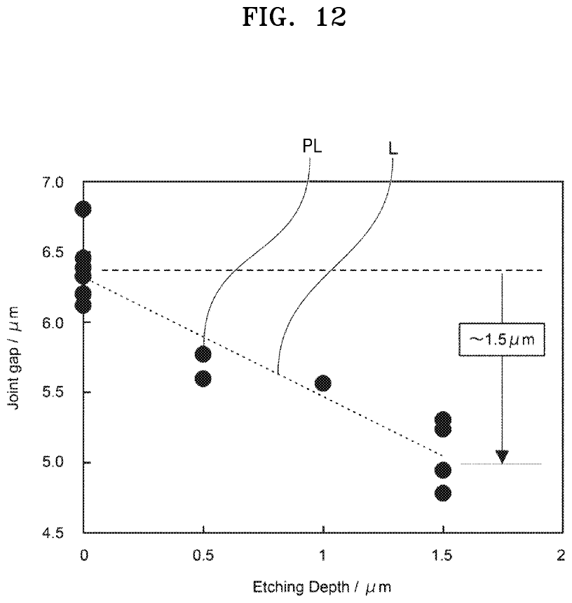

Next, with reference to FIG. 12, a relationship between the etching depth ED (μm) of the concave portion 30 and the joint gap Jg (μm) is described.

Firstly, two semiconductor devices 1 have been manufactured based on the method of manufacturing the semiconductor device 1 described above. In this case, an Si chip has been used as the semiconductor chip 20, Au-plated Ni has been used as the first electrode 21 and the second electrode 22, and Cu has been used as the wiring 23. The first insulating layer 26 and the second insulating layer 27 used in the experiment described above have been used. A Sn—Ag-based lead-free solder has been used as the solder bump 24. The non-conductive layer 28 has been prepared by laminating the NCF having a thickness of 6.0 μm on the entire surface on the side of the first main surface 20a. The concave portion 30 can be formed in the same method as that of the experiment described above.

The semiconductor devices 1 manufactured in this manner have been bonded to each other by using the method of bonding a semiconductor device described above. A load at the time of thermocompression has been 3 MPa, and a peak temperature at the manufacturing time point has been 250 °C.

A plot PL of FIG. 12 indicates a relationship between the depth ED of the concave portion 30 and the joint gap Jg, which is actually measured. A graph L may have an approximate straight line of the plots P. As is apparent from the graph L, it may be identified that the joint gap Jg decreases as the depth ED of the concave portion 30 increases. In the present experiment, the joint gap Jg was successfully reduced by up to 1.5 μm. The success may be possible because, as described above, the non-conductive material flows into the concave portion 30 when the semiconductor devices 1 are bonded together. In addition, the height of the NCF fillet exhibits little variation, despite a reduction in the joint gap Jg. When the depth ED of the concave portion 30 is about 0.5 μm and the joint gap Jg is about 6.0 μm, the height of the NCF fillet may be about 60.0 μm, and even when the depth ED of the concave portion 30 is about 1.5 μm and the joint gap Jg is about 5.0 μm, the height of the NCF fillet may also be about 60.0 μm. This result may mean that when the joint gap Jg is the same, the amount of NCF fillet may be reduced. Thus, according to some embodiments, semiconductor devices may be bonded to each other with a smaller load, and in addition, the amount of NCF fillet may be reduced.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a subcombination or variation of a subcombination.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

Although the disclosure by the inventors has been described in detail based on some embodiments, the disclosure is not limited thereto, and various modifications thereof may be possible without departing from the gist.

For example, in some embodiments, the concave portion 30 may also be formed between the first electrodes 21. In this case, for example, during the thermocompression, the non-conductive material may flow into the concave portion 30 formed between the first electrodes 21. Furthermore, in the example described above, when the concave portion 30 reaches the semiconductor chip 20, the oxide layer 33 may be formed, but the oxide layer 33 may not be formed.

1. A semiconductor device comprising:
a semiconductor chip including a first main surface and a second main surface opposite to the first main surface;
a wiring that extends through the semiconductor chip from the first main surface to the second main surface;
a plurality of first electrodes overlapping the wiring on the first main surface;
a solder bump on each first electrode of the plurality of first electrodes;
a non-conductive layer on the first main surface and the solder bump; and
a plurality of second electrodes overlapping the wiring on the second main surface,
wherein the semiconductor chip comprises a concave portion in at least one of a space between adjacent first electrodes of the plurality of first electrodes or a space between adjacent second electrodes of the plurality of second electrodes.

2. The semiconductor device of claim 1, wherein the concave portion is in the space between the adjacent second electrodes of the plurality of second electrodes.

3. The semiconductor device of claim 1, comprising an insulating layer on at least one of the first main surface or the second main surface, wherein at least a portion of the concave portion is provided in the insulating layer.

4. The semiconductor device of claim 3,
wherein the insulating layer comprises an opening exposing the concave portion in the semiconductor chip.

5. The semiconductor device of claim 4, comprising an oxide layer on a surface of the concave portion.

6. The semiconductor device of claim 1,
wherein the concave portion extends from a back surface of a first electrode of the plurality of first electrodes to a back surface of a second electrode of the plurality of second electrodes.

7. The semiconductor device of claim 1,
wherein a side surface of the concave portion has at least one of an inclined planar shape or a curved shape.

8. The semiconductor device of claim 1,
wherein the semiconductor device comprises a first semiconductor device and a second semiconductor device,
wherein the semiconductor device comprises:
at least one bonding portion comprising one of the plurality of first electrodes of the first semiconductor device and one of the plurality of second electrodes of the second semiconductor device,
wherein the one of the plurality of first electrodes and the one of the plurality of second electrodes are bonded to each other by the solder bump, and
wherein the non-conductive layer of the first semiconductor device at least partially fills at least a space between the at least one bonding portion and the concave portion, the concave portion being in the first semiconductor device or in the second semiconductor device.

9. A method of manufacturing a semiconductor device, the method comprising:
forming, in a semiconductor substrate including a first main surface and a second main surface opposite to the first main surface, a plurality of wirings each extending between the first main surface and the second main surface;
forming a plurality of first electrodes respectively on the plurality of wirings and the first main surface;
forming a solder bump on each first electrode of the plurality of first electrodes;
forming a plurality of second electrodes respectively on the plurality of wirings and the second main surface;
forming a concave portion in the semiconductor substrate and in at least one of a space between the plurality of first electrodes or a space between the plurality of second electrodes; and
forming a non-conductive layer on the first main surface and the solder bump.

10. The method of claim 9, comprising forming an insulating layer on at least one of the first main surface or the second main surface.

11. The method of claim 10,
wherein forming the concave portion comprises etching the insulating layer.

12. The method of claim 11,
wherein forming the concave portion comprises etching the insulating layer and the semiconductor substrate.

13. The method of claim 11,
wherein at least a part of the concave portion overlaps at least one of a first electrode of the plurality of first electrodes or a second electrode of the plurality of second electrodes in a vertical direction.

14. The method of claim 11,
wherein a side surface of the concave portion has at least one of an inclined planar shape or a curved shape.

15. The method of claim 12,
wherein forming the concave portion comprises oxidizing a surface of the concave portion in the semiconductor substrate.

16. The method of claim 9, wherein forming the wiring comprises forming the plurality of wirings using a through-silicon via (TSV) technique.

17. A method of bonding a plurality of semiconductor devices, the method comprising:
preparing a first semiconductor device according to claim 1 and preparing a second semiconductor device according to claim 1;
stacking the first semiconductor device and the second semiconductor device, such that a first electrode of the first semiconductor device faces a second electrode of the second semiconductor device; and
forming at least one bonding portion by bonding the first electrode of the first semiconductor device to the second electrode of the second semiconductor device using a solder bump, and at least partially filling a non-conductive layer at least in a space between the at least one bonding portion and a concave portion in each of the first semiconductor device and the second semiconductor device.

18. The method of claim 17,
wherein forming the at least one bonding portion comprises forming the at least one bonding portion by melting the solder bump and the non-conductive layer using thermocompression.

19. The method of claim 17,
wherein the first semiconductor device comprises a first insulating layer on at least one of a first main surface or a second main surface of the first semiconductor device, and
the second semiconductor device comprises a second insulating layer on at least one of a first main surface and a second main surface of the second semiconductor device.

20. The method of claim 17,
wherein the first semiconductor device comprises a first oxide layer on a surface of a first concave portion of a first semiconductor chip, and
wherein the second semiconductor device comprises a second oxide layer on a surface of a second concave portion of a second semiconductor chip.
